(19) United States
(12) Patent Application Publication
(10) Pub. No.: US 2025/0174547 A1
(43) Pub. Date: May 29, 2025

(54) SEMICONDUCTOR DEVICE AND METHOD OF MANUFACTURING THE SAME

(71) Applicant: DENSO CORPORATION, Kariya-city (JP)

(72) Inventors: Eisuke BANNO, Kariya-city (JP); Yosuke MITANI, Kariya-city (JP)

(21) Appl. No.: 19/040,749

(22) Filed: Jan. 29, 2025

Related U.S. Application Data
(63) Continuation of application No. PCT/JP2023/034687, filed on Sep. 25, 2023.

(30) Foreign Application Priority Data
Sep. 30, 2022 (JP) 2022-158461

(51) Int. Cl. H01L 23/522; H01L 21/762; H01L 23/528; H10D 1/68; H10D 86/00; H10D 86/01

(52) U.S. Cl. CPC H01L 23/5223; H01L 21/76275; H01L 21/76283; H01L 23/528; H01L 23/5283; H10D 1/714; H10D 1/716; H10D 86/01; H10D 86/201

(57) ABSTRACT

A semiconductor device has a substrate and a capacitor. The capacitor is disposed on one surface of the substrate. The capacitor has two electrodes and a dielectric film arranged between the two electrodes. The substrate has a trench penetrating the substrate within an opposing region of the substrate opposing the capacitor.

### CROSS REFERENCE TO RELATED APPLICATIONS

The present application is a continuation application of International Patent Application No. PCT/JP2023/034687 filed on Sep. 25, 2023, which designated the U.S. and claims the benefit of priority from Japanese Patent Application No. 2022-158461 filed on Sep. 30, 2022. The entire disclosures of all of the above applications are incorporated herein by reference.

### TECHNICAL FIELD

The present disclosure relates to a semiconductor device including a capacitor and a manufacturing method of the semiconductor device.

### BACKGROUND

A semiconductor device includes a capacitor having a metal-insulator-metal (MIM) structure that is configured with metal wiring layers and an insulating layer disposed between the metal wiring layers.

### SUMMARY

According to one aspect of the present disclosure, a semiconductor device includes a substrate, and a capacitor disposed on the substrate. The capacitor has two electrodes and a dielectric film disposed between the two electrodes. The substrate has a trench penetrating the substrate within an opposing region of the substrate that opposes the capacitor.

### BRIEF DESCRIPTION OF DRAWINGS

FIG. 1 is a plan view of a semiconductor device according to a first embodiment.

FIG. 2 is a cross-sectional view taken along line II-II of FIG. 1.

FIG. 3A is a cross-sectional view illustrating a manufacturing process of the semiconductor device of FIG. 2.

FIG. 3B is a cross-sectional view illustrating a manufacturing process of the semiconductor device subsequent to FIG. 3A.

FIG. 3C is a cross-sectional view illustrating a manufacturing process of the semiconductor device subsequent to FIG. 3B.

FIG. 4A is a cross-sectional view illustrating a manufacturing process of the semiconductor device subsequent to FIG. 3C.

FIG. 4B is a cross-sectional view illustrating a manufacturing process of the semiconductor device subsequent to FIG. 4A.

FIG. 4C is a cross-sectional view illustrating a manufacturing process of the semiconductor device subsequent to FIG. 4B.

FIG. 4D is a cross-sectional view illustrating a manufacturing process of the semiconductor device subsequent to FIG. 4C.

FIG. 5A is a cross-sectional view showing a manufacturing process of the semiconductor device subsequent to FIG. 4D.

FIG. 5B is a cross-sectional view illustrating a manufacturing process of the semiconductor device subsequent to FIG. 5A.

FIG. 6 is a cross-sectional view of a semiconductor device in which a wide trench is formed.

FIG. 7 is a cross-sectional view of a semiconductor device in which a narrow trench is formed.

FIG. 8 is a cross-sectional view of a semiconductor device according to a second embodiment.

FIG. 9A is a cross-sectional view illustrating a manufacturing process of the semiconductor device of FIG. 8.

FIG. 9B is a cross-sectional view illustrating a manufacturing process of the semiconductor device subsequent to FIG. 9A.

FIG. 9C is a cross-sectional view illustrating a manufacturing process of the semiconductor device subsequent to FIG. 9B.

FIG. 10 is a cross-sectional view of a semiconductor device according to another embodiment.

FIG. 11 is a plan view of a semiconductor device according to another embodiment.

FIG. 12 is a cross-sectional view taken along line XII-XII of FIG. 11.

FIG. 13 is a cross-sectional view of a semiconductor device according to another embodiment.

FIG. 14 is a plan view of a semiconductor device according to another embodiment.

FIG. 15 is a plan view of a semiconductor device according to another embodiment.

FIG. 16 is a plan view of a semiconductor device according to another embodiment.

FIG. 17 is a plan view of a semiconductor device according to another embodiment.

FIG. 18 is a plan view of a semiconductor device according to another embodiment.

### DETAILED DESCRIPTION

A semiconductor device includes a capacitor having a metal-insulator-metal (MIM) structure configured with an insulating layer and metal wiring layers disposed on both sides of the insulating layer. Specifically, this semiconductor device has a substrate on which a semiconductor element such as diode or transistor is formed. A capacitor is formed on the substrate by stacking an upper electrode and a lower electrode with an insulating layer interposed between the electrodes. In a semiconductor device having such a configuration, a parasitic capacitance occurs between the lower electrode of the capacitor and the substrate. Since power consumption increases in proportion to the magnitude of this parasitic capacitance, it is required to reduce the parasitic capacitance in order to reduce the power consumption of the semiconductor device.

For example, the parasitic capacitance can be reduced by decreasing the area of the electrode such that the opposing area between the electrode and the substrate is made smaller. Alternatively, the parasitic capacitance can be reduced by moving the lower electrode to a higher layer, away from the substrate.

However, these methods may result in reduced capacitor performance. Specifically, if the electrode area is reduced, the capacitance of the capacitor decreases. In case where the lower electrode is moved to an upper layer, the distance between the electrodes is to be reduced in order to restrict an increase in the size of the semiconductor device. In this case, the electrical insulation between the electrodes is lowered.

The present disclosure provides a semiconductor device and a manufacturing method thereof, to reduce parasitic capacitance while suppressing deterioration in capacitor performance.

According to one aspect of the present disclosure, a semiconductor device includes a substrate and a capacitor disposed on one side of the substrate. The capacitor has two electrodes and a dielectric film disposed between the two electrodes. A trench penetrating the substrate is formed in an opposing region of the substrate that opposes the capacitor.

In this manner, by forming the trench penetrating the substrate within the opposing region of the substrate opposing the capacitor, the effective opposing area between the electrode and the substrate is reduced, making it possible to reduce parasitic capacitance. Furthermore, since there is no need to change the electrode area, deterioration in the performance of the capacitor can be suppressed.

According to another aspect, a semiconductor device includes a substrate and a capacitor disposed on one side of the substrate. The capacitor has two electrodes and a dielectric film disposed between the two electrodes. The substrate has an opposing region opposing the capacitor. A thickness of the opposing region is thinner than an outer region outside of the opposing region by a recess recessed from the one side, and a space is formed inside the opposing region.

Accordingly, the distance between the substrate and the electrode becomes large in the opposing region, so that the parasitic capacitance can be reduced. Furthermore, since there is no need to change the electrode area, deterioration in the performance of the capacitor can be suppressed.

According to another aspect, a method of manufacturing a semiconductor device having a capacitor includes: preparing a substrate; forming a capacitor on one side of the substrate, the capacitor having two electrodes and a dielectric film disposed between the two electrodes; and forming a trench penetrating the substrate in an opposing region of the substrate opposing the capacitor.

By forming the trench in this manner, the parasitic capacitance is reduced. For example, by forming a buried film to cover an inner wall of the trench, the effective opposing area between the electrode and the substrate is reduced, such that the parasitic capacitance can be reduced. Furthermore, the one side of the substrate is depressed by softening the substrate by heat treatment to close the opening of the trench by migration. Thus, since the distance between the substrate and the electrode is increased, the parasitic capacitance is reduced. Furthermore, since there is no need to change the electrode area, deterioration in the performance of the capacitor can be suppressed.

Hereinafter, embodiments of the present disclosure will be described with reference to the drawings. In the following embodiments, the same or equivalent parts are denoted by the same reference numerals as each other, and explanations will be provided to the same reference numerals.

### First Embodiment

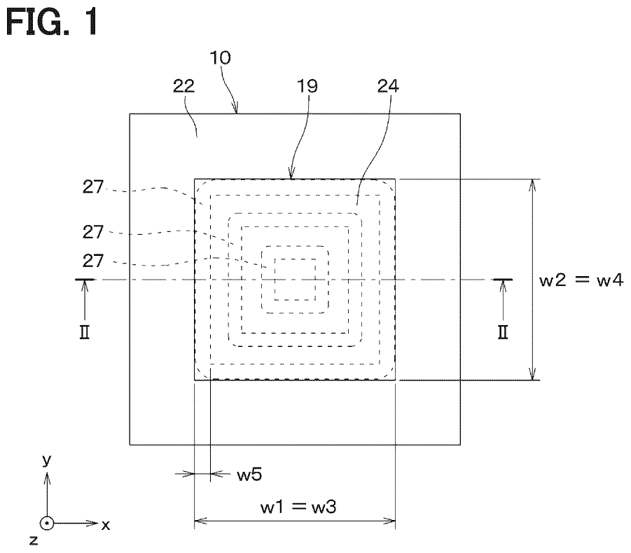

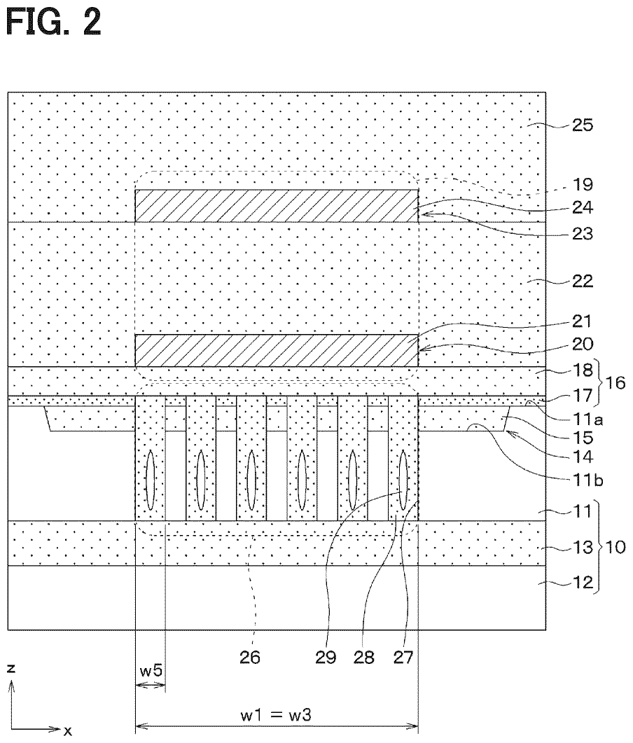

A first embodiment is described below. A semiconductor device of this embodiment shown in FIGS. 1 and 2 has a stacked board 10 on which semiconductor elements such as transistor (not shown) are formed. In FIG. 1, a protective film 25, which will be described later, is omitted.

The stacked board 10 is a silicon on insulator (SOI) substrate having a structure in which a first semiconductor substrate 11 and a second semiconductor substrate 12 are stacked with an insulating layer 13 interposed therebetween. The first semiconductor substrate 11 and the second semiconductor substrate 12 are made of Si (silicon) or the like, and the insulating layer 13 is made of SiO₂ (silicon oxide) or the like.

The stacked board 10 has a shallow trench isolation (STI) portion 14 for isolating plural semiconductor elements (not shown). Specifically, a surface of the first semiconductor substrate 11 opposite to the insulating layer 13 is defined as a first surface 11a, and the first semiconductor substrate 11 has a recess 11b open in the first surface 11a. The recess 11b is filled with an oxide film 15 made of SiO₂ or the like, which electrically isolates the semiconductor elements.

An interlayer film 16 is arranged on the first surface 11a and the oxide film 15. The interlayer film 16 electrically insulates the first semiconductor substrate 11 from a wiring layer 20, which will be described later. The interlayer film 16 includes a nitride film 17 arranged on the first semiconductor substrate 11 and the oxide film 15, and an oxide film 18 disposed on the nitride film 17. The nitride film 17 is made of SiN (silicon nitride) or the like, and the oxide film 18 is made of SiO₂ or the like.

A capacitor 19 is formed at an upper part of the oxide film 18 adjacent to the STI portion 14. Specifically, the wiring layer 20 made of Al (aluminum) or the like is arranged on the oxide film 18. The wiring layer 20 is patterned into a desired shape, and a part of the wiring layer 20 forms a first electrode 21 of the capacitor 19. A dielectric film 22 made of SiO₂ or the like is formed on the wiring layer 20 so as to cover the wiring layer 20 and the oxide film 18 exposed from the wiring layer 20. A wiring layer 23 made of Al or the like is arranged on the dielectric film 22. The wiring layer 23 is patterned into a desired shape, and a part of the wiring layer 23 forms a second electrode 24 of the capacitor 19. For example, in FIGS. 1 and 2, a part of the wiring layer 20, 23 that connects the first electrode 21 or the second electrode 24 to an external circuit is not shown.

Two directions parallel to the first surface 11a and perpendicular to each other are defined as an x direction and a y direction, respectively. A direction perpendicular to the x direction and the y direction is defined as a z direction. As described above, the capacitor 19 has a configuration in which the first electrode 21 and the second electrode 24 are stacked in the z direction with the dielectric film 22 interposed therebetween. The first electrode 21 and the second electrode 24 are formed in a rectangular shape when viewed in the z direction so that their widths in the x direction and the y direction are equal to each other.

In the capacitor 19, the first electrode 21 may be at a low potential and the second electrode 24 may be at a high potential, or the first electrode 21 may be at a high potential and the second electrode 24 may be at a low potential.

A protective film 25 made of SiO₂ or the like is formed on the second electrode 24 so as to cover the second electrode 24 and the dielectric film 22 exposed from the second electrode 24.

A region of the first semiconductor substrate 11 opposing the capacitor 19 is defined as an opposing region 26. A trench 27 penetrating the first semiconductor substrate 11 is formed in the opposing region 26. The trench 27 is formed so as to penetrate the nitride film 17, the oxide film 15 and the first semiconductor substrate 11 and reach the insulating layer 13.

The inside of the trench 27 is filled with a buried film 28. As described later, the buried film 28 of this embodiment includes two layers, specifically, a first filling film 28a and a second filling film 28b. The interlayer film 16 is made of the second filling film 28b. The buried film 28 is composed of a non-doped oxide film or a doped oxide film such as BPSG which is an abbreviation for borophospho-silicate glass.

The buried film 28 is formed to cover the surface of the insulating layer 13 exposed from the trench 27 and the inner wall surface of the trench 27, and to close the opening of the trench 27 opposite to the insulating layer 13. However, the buried film 28 does not fill the entire inside of the trench 27, and a space 29 surrounded by the buried film 28 is formed inside the trench 27.

The plural trenches 27 are open in concentric rectangular shape on the first surface 11a. The four sides of each trench 27 extend along the x direction or the y direction. The widths of the trench region in which the trenches 27 are formed in the x direction and the y direction are respectively denoted by w1 and w2. In this embodiment, the width of the outermost trench 27 in the x direction is w1, and the width of the outermost trench 27 in the y direction is w2.

As described above, the upper surfaces of the first electrode 21 and the second electrode 24 are rectangular, and the opposing region 26 is a rectangular region having the same dimensions as the first electrode 21 and the second electrode 24 when viewed in the z direction. The width of the opposing region 26 in the x direction is denoted by w3, and the width of the opposing region 26 in the y direction is denoted by w4.

The opposing region 26 and the trench region of the first semiconductor substrate 11 in which the trenches 27 are formed are at the same position in the x and y directions and have the same width (that is, w1=w3, w2=w4). In the xy plane, the outer edge of the outermost trench 27 coincides with the outer edges of the opposing region 26, the first electrode 21 and the second electrode 24.

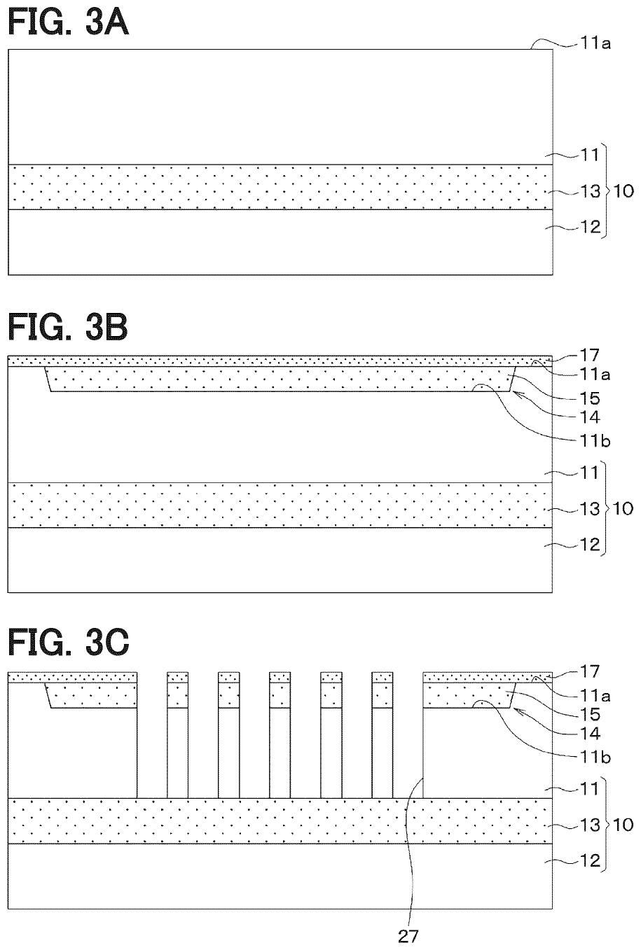

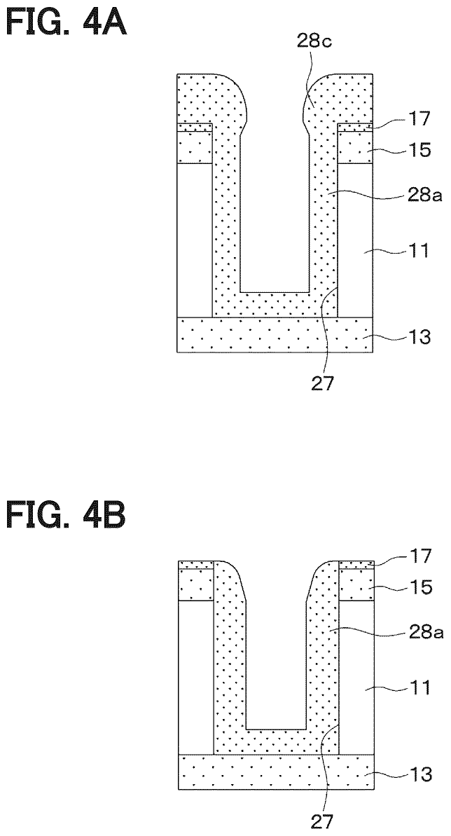

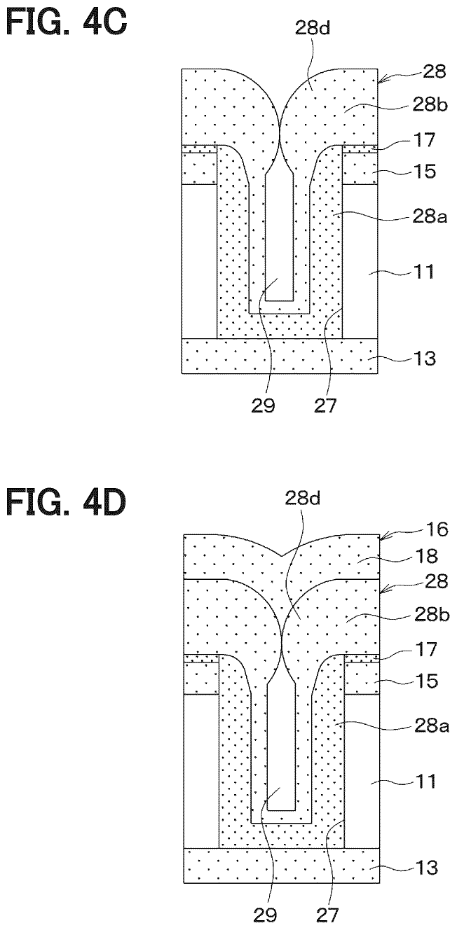

A method for manufacturing the semiconductor device will be described with reference to FIGS. 3A to 5B. FIGS. 4A to 4D are enlarged cross-sectional views of the trench 27.

In the process shown in FIG. 3A, the stacked board 10 is prepared. For example, a Si substrate constituting the first semiconductor substrate 11 and a Si substrate constituting the second semiconductor substrate 12 are prepared. An oxide film constituting the insulating layer 13 is formed on one or both of the Si substrates by thermal oxidation. Then, the two Si substrates are bonded together with this oxide film to form the stacked board 10.

In the process shown in FIG. 3B, the STI portion 14 and the nitride film 17 are formed. For example, the recess 11b is formed in the first surface 11a by anisotropic etching using a mask (not shown), and the recess 11b is filled with an oxide film by CVD to form the oxide film 15. Thereafter, the nitride film 17 is formed by CVD so as to cover the first surface 11a and the oxide film 15. CVD stands for Chemical Vapor Deposition.

In the process shown in FIG. 3C, the trench 27 penetrating the first semiconductor substrate 11 is formed in a portion of the first semiconductor substrate 11 that will become the opposing region 26. For example, the nitride film 17, the oxide film 15, and the first semiconductor substrate 11 are sequentially removed by anisotropic etching such as RIE using a mask (not shown), to form the trench 27 reaching the insulating layer 13. RIE is an abbreviation for Reactive Ion Etching.

In the processes shown in FIGS. 4A to 4D, the buried film 28 is formed inside the trench 27, and the oxide film 18 is formed on the buried film 28. Here, a case will be described in which the buried film 28 is composed of a first filling film 28a and a second filling film 28b.

In the process shown in FIG. 4A, a first filling film 28a is formed by CVD to cover the inner wall of the trench 27. Specifically, the first filling film 28a is formed to cover the inner wall of the trench 27, as well as the surface of the insulating layer 13 exposed from the trench 27 and the surface of the nitride film 17. At the opening of the trench 27, an overhang portion 28c of the first filling film 28a is formed.

In the process shown in FIG. 4B, the first filling film 28a formed outside the trench 27 is removed by etching. As a result, the nitride film 17 is exposed outside the trench 27. Moreover, the overhang portion 28c is removed, and the opening of the first filling film 28a formed in the trench 27 becomes wider.

In the process shown in FIG. 4C, a second filling film 28b is formed by CVD to cover the first filling film 28a and the nitride film 17. In the second filling film 28b, an overhang portion 28d is formed at the opening of the trench 27 in the same manner as in the first filling film 28a, and the opening of the trench 27 is closed by the overhang portion 28d. As a result, a space 29 surrounded by the second filling film 28b is formed inside the trench 27.

The minimum pressure in the space 29 is approximately the same as the pressure in the chamber used to form the second filling film 28b. In the space 29, silane, nitrogen, TEOS, or the like used as a material gas for the second filling film 28b enters due to degassing from the second filling film 28b during a heat treatment in a subsequent process. TEOS is an abbreviation for tetra-ethyl ortho-silicate.

In the process shown in FIG. 4D, an oxide film 18 is formed by CVD to cover the second filling film 28b. As a result, an interlayer film 16 is formed on the first semiconductor substrate 11. As shown in FIG. 4D, the second filling film 28b is interposed between the nitride film 17 and the oxide film 18, and the interlayer film 16 is configured to include the second filling film 28b.

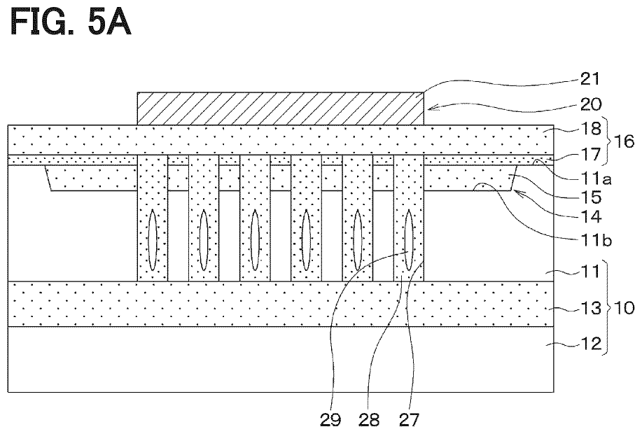

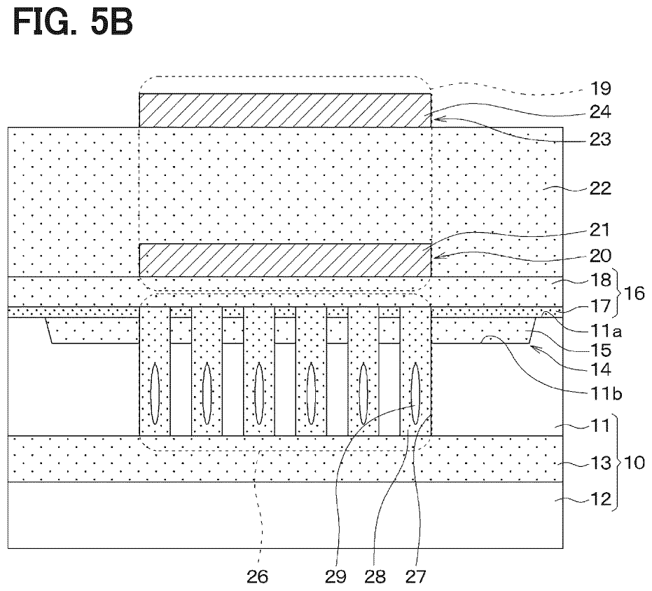

In the process shown in FIG. 5A, a conductive material such as Al is formed on the oxide film 18 by sputtering, and is patterned into a desired shape to form the wiring layer 20 and the first electrode 21.

In the process shown in FIG. 5B, the dielectric film 22 is formed by CVD to cover the wiring layer 20 and the oxide film 18 exposed from the wiring layer 20. Then, a film of a conductive material such as Al is formed on the dielectric film 22 by sputtering, and is patterned into a desired shape to form the wiring layer 23 and the second electrode 24. As a result, the capacitor 19 is formed, which is composed of the first electrode 21, the dielectric film 22, and the second electrode 24.

Thereafter, a protective film 25 is formed by CVD to cover the second electrode 24 and the dielectric film 22 exposed from the second electrode 24. In this manner, the semiconductor device shown in FIG. 2 is manufactured.

The effect of this embodiment is described. The capacitance C of a capacitor having two electrodes and a dielectric disposed between the two electrodes is represented as C=εᵣε₀S/d, where εᵣ is the relative dielectric constant of the dielectric, ε₀ is the dielectric constant of a vacuum, S is the area of the electrode, and d is the distance between the electrodes.

Therefore, in a semiconductor device in which a capacitor is formed on a semiconductor substrate, for example, the parasitic capacitance can be reduced by reducing the area of the electrode opposing the semiconductor substrate. Furthermore, by forming the electrode in an upper wiring layer, the distance between the electrode and the semiconductor substrate becomes large, and the parasitic capacitance can be reduced.

However, these methods may result in reduced capacitor performance. For example, if the electrode area is reduced, the capacitance of the capacitor decreases. Furthermore, if the lower electrode is formed in an upper wiring layer, the distance between the electrodes is to be reduced in order to restrict an increase in the size of the semiconductor device, which reduces the insulation between the electrodes.

In contrast, in this embodiment, by forming the trench 27 penetrating the first semiconductor substrate 11 in the opposing region 26, the effective opposing area between the first electrode 21 and the first semiconductor substrate 11 is reduced, such that the parasitic capacitance is reduced. Furthermore, since there is no need to change the area or position of the first electrode 21 to reduce the parasitic capacitance, the opposing area and distance between the first electrode 21 and the second electrode 24 in the capacitor 19 can be maintained, such that performance degradation of the capacitor 19 can be suppressed.

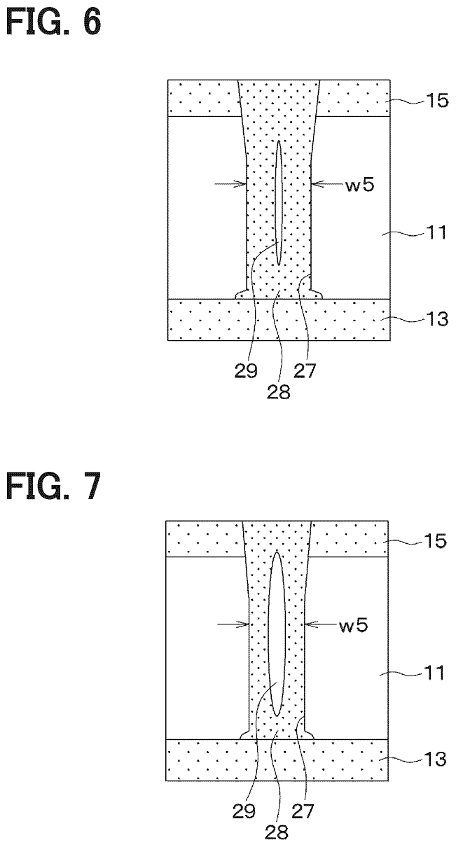

As shown in FIGS. 6 and 7, by reducing the width w5 of the trench 27, the opening of the trench 27 is quickly closed in the process shown in FIG. 4C, such that the space 29 becomes larger. The width w5 represents a width of each side of a rectangle constituting the trench 27 in a direction perpendicular to the trench-extending direction and the z direction. That is, a part of the trench 27 extending in the x direction has the width w5 in the y direction, and a part of the trench 27 extending in the y direction has the width w5 in the x direction.

The relative dielectric constant of SiO₂ is 3.8, and the relative dielectric constant of a vacuum is 1. Therefore, by increasing the space 29 and reducing the proportion of the buried film 28 inside the trench 27, the dielectric constant of the entire trench 27 is reduced. Thus, the parasitic capacitance between the first electrode 21 and a part of the first semiconductor substrate 11 that forms the inner wall of the trench 27 is reduced. Furthermore, by reducing the width w5, the layout pitch of the trenches 27 can be made finer, such that the effective opposing area between the first electrode 21 and the first semiconductor substrate 11 can be made smaller. According to the inventors' investigations, in order to efficiently reduce the parasitic capacitance by lowering the relative dielectric constant of the entire trench 27 and reducing the effective opposing area between the first electrode 21 and the first semiconductor substrate 11, it is desirable to set the width w5 to 0.7 μm or more and 1.5 μm or less.

The width of the space 29 is preferably set to be not less than 20 nm and not more than 120 nm. Here, the width of the space 29 is defined in the same direction as the width w5. That is, in a part of the trench 27 extending in the x direction, it is desirable to set the width of the space 29 in the y direction within the above range. In a part of the trench 27 extending in the y direction, it is desirable to set the width of the space 29 in the x direction within the above range.

Moreover, by forming the recess 11b deeper in the process shown in FIG. 3B, the distance between the first electrode 21 and the first semiconductor substrate 11 increases, and the parasitic capacitance can be further reduced. For example, it is desirable for the depth of the recess 11b to be 0.32 μm or more. Even in a configuration in which the trench 27 is not formed in the first semiconductor substrate 11, the parasitic capacitance can be reduced by forming the recess 11b deeply, but the parasitic capacitance can be further reduced by forming the trench 27.

As described above, in this embodiment, the trench 27 penetrating the first semiconductor substrate 11 is formed in the opposing region 26 of the first semiconductor substrate 11 that opposes the capacitor 19. This makes it possible to reduce the parasitic capacitance between the first semiconductor substrate 11 and the capacitor 19 while suppressing deterioration in the performance of the capacitor 19.

Further, according to the embodiment, it is possible to achieve the following advantageous effects.

(1) The opening of the trench 27 is covered with the interlayer film 16, and the space 29 is formed inside the trench 27. This increases the distance between the first semiconductor substrate 11 and the first electrode 21 compared to a case where the capacitor 19 is formed directly above the trench 27, thereby further reducing the parasitic capacitance between the first electrode 21 and the first semiconductor substrate 11. Furthermore, since the relative dielectric constant of the entire trench 27 is reduced, the parasitic capacitance between the first electrode 21 and a part of the first semiconductor substrate 11 that constitutes the inner wall of the trench 27 can be reduced.

(2) The first filling film 28a is formed to cover the inner wall of the trench 27, and the second filling film 28b is formed to cover the first filling film 28a. The opening of the trench 27 is blocked by the overhang of the second filling film 28b, thereby forming the space 29. In this way, by blocking the opening of the trench 27 by filling twice, the surface of the oxide film 18 at the top of the trench 27 becomes flatter than when the opening is blocked by filling once, making it easier to form the wiring layer 20.

### Second Embodiment

A second embodiment is described. In this embodiment, the configuration of the first semiconductor substrate 11 is changed from that of the first embodiment, but other aspects are similar to those of the first embodiment, so only the parts that differ from the first embodiment will be described.

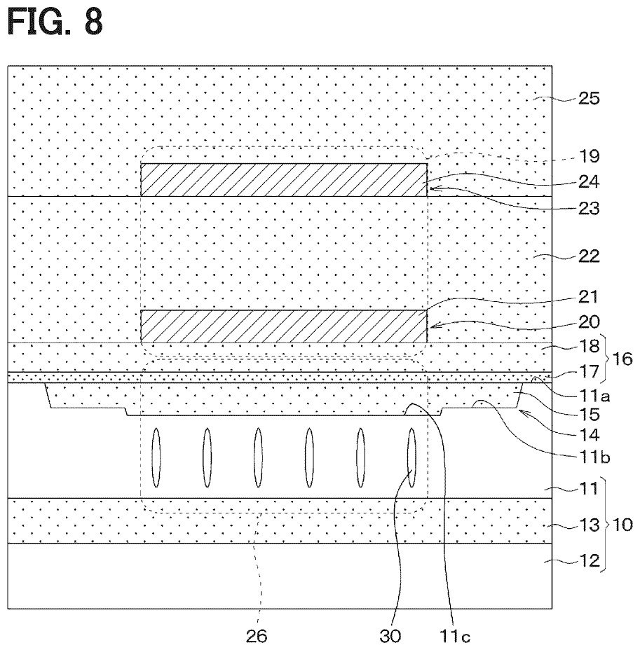

As shown in FIG. 8, the first semiconductor substrate 11 of this embodiment has a recess 11c formed at the bottom of the recess 11b, and the recess 11c is open toward the first surface 11a. The recess 11c is formed in the opposing region 26, so that the opposing region 26 is made thinner than a part of the first semiconductor substrate 11 located outside the opposing region 26. In the opposing region 26, a space 30 is formed inside the first semiconductor substrate 11.

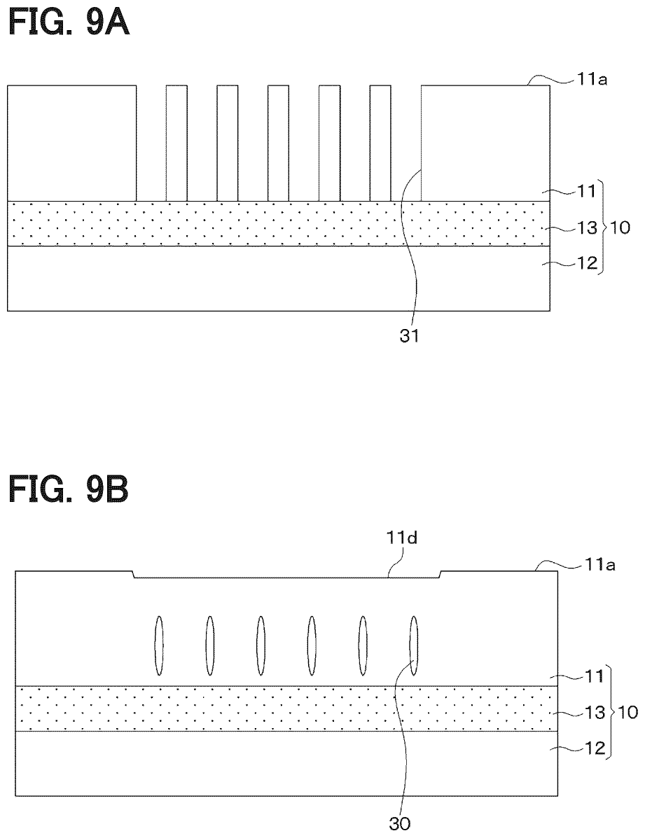

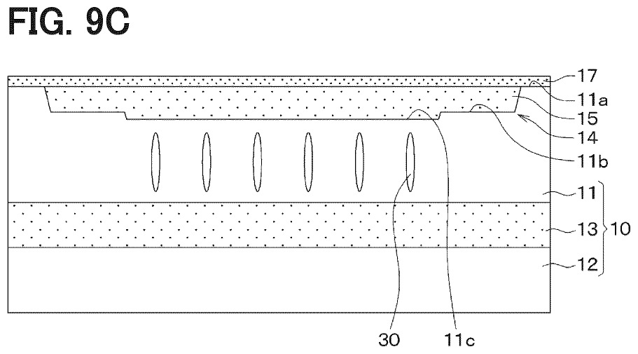

A method of manufacturing the semiconductor device of this embodiment will be described. In this embodiment, after the process shown in FIG. 3A, as shown in FIG. 9A, plural trenches 31 are formed in a part of the first semiconductor substrate 11 to be the opposing region 26 so as to penetrate the first semiconductor substrate 11 by anisotropic etching such as RIE using a mask (not shown).

In the process shown in FIG. 9B, the first semiconductor substrate 11 is softened by a heat treatment such as hydrogen annealing, and the opening of the trench 31 is blocked by migration of Si that constitutes the first semiconductor substrate 11, thereby forming multiple spaces 30 inside the first semiconductor substrate 11. As a result, the first surface 11a of the first semiconductor substrate 11 to be the opposing region 26 is depressed, and the recess 11d is formed to be open in the first surface 11a.

In the process shown in FIG. 9C, the STI portion 14 and the nitride film 17 are formed. Specifically, the recess 11b is formed in the first surface 11a by anisotropic etching using a mask (not shown). Since the recess 11d is formed in the part to be the opposing region 26, the recess 11c is formed in the bottom of the recess 11b by this anisotropic etching. After the recess 11b and the recess 11c are formed, the recess 11b and the recess 11c are filled with an oxide film by CVD to form the oxide film 15. Thereafter, the nitride film 17 is formed by CVD to cover the first surface 11a and the oxide film 15.

Subsequently, the wiring layer 20, the protective film 25 and the like are formed in the same manner as in the first embodiment. In this manner, the semiconductor device shown in FIG. 8 is manufactured.

The present embodiment can achieve the same effects as those of the first embodiment from the same configuration and operation as those of the first embodiment.

According to the present embodiment, it is possible to achieve the following advantageous effects.

(1) The opposing region 26 of the first semiconductor substrate 11 is made thinner than the peripheral region of the opposing region 26 by the recess 11c that opens toward the first surface 11a, and the space 30 is formed inside the opposing region 26. According to this, the distance between the first semiconductor substrate 11 and the first electrode 21 becomes large in the opposing region 26, so that the parasitic capacitance can be reduced while suppressing the deterioration of the performance of the capacitor 19.

(2) The first semiconductor substrate 11 is softened by heat treatment, and the opening of the trench 31 is blocked by migration to form the space 30 inside the first semiconductor substrate 11. As a result, the first surface 11a is depressed by migration in the opposing region 26, and the distance between the first semiconductor substrate 11 and the first electrode 21 increases, so that the parasitic capacitance can be reduced while suppressing deterioration in the performance of the capacitor 19. Furthermore, since the process of filling the trench 31 with an oxide film or the like is not required, the manufacturing cost of the semiconductor device can be reduced.

### Other Embodiments

The present disclosure is not limited to the above embodiments, and can be appropriately modified. Individual elements or features of a particular embodiment are not necessarily essential unless it is specifically stated that the elements or the features are essential in the foregoing description, or unless the elements or the features are obviously essential in principle. Further, in each of the embodiments, when numerical values such as the number, numerical value, quantity, range, and the like of the constituent elements of the embodiment are referred to, except in the case where the numerical values are expressly indispensable in particular, the case where the numerical values are obviously limited to a specific number in principle, and the like, the present disclosure is not limited to the specific number. Furthermore, a shape, positional relationship or the like of a structural element, which is referred to in the embodiments described above, is not limited to such a shape, positional relationship or the like, unless it is specifically described or obviously necessary to be limited in principle.

For example, in the first embodiment, the space 29 does not necessarily have to be formed inside the trench 27. In the second embodiment, the space 30 does not necessarily have to be formed in the opposing region 26.

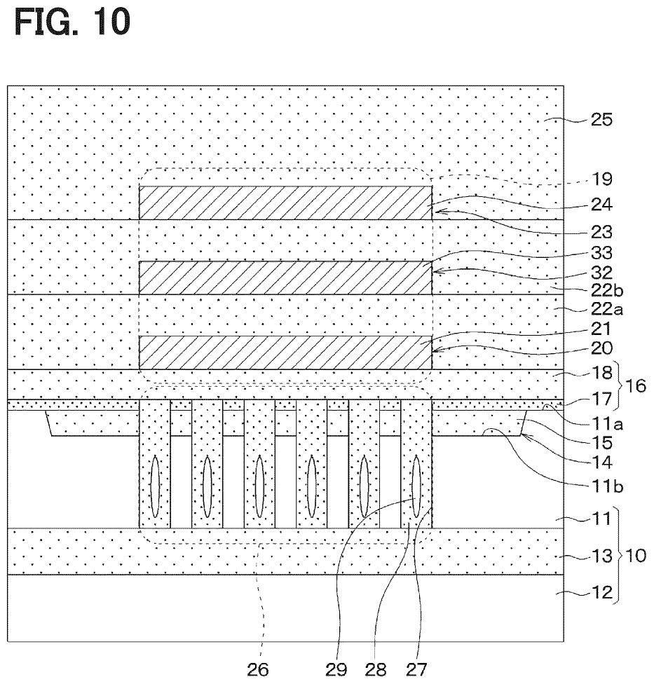

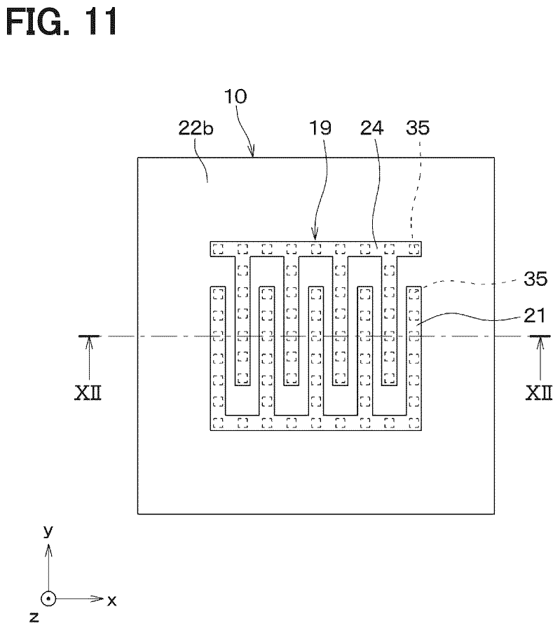

Furthermore, three or more wiring layers may be formed. For example, as shown in FIG. 10, the capacitor 19 may have three electrodes. In the example shown in FIG. 10, a first dielectric film 22a made of SiO₂ or the like is arranged on the wiring layer 20 and on the oxide film 18 exposed from the wiring layer 20. A wiring layer 32 made of Al or the like is arranged on the first dielectric film 22a. The wiring layer 32 is patterned into a desired shape, and a part of the wiring layer 32 forms a third electrode 33 of the capacitor 19. A second dielectric film 22b made of SiO₂ or the like is formed on the third electrode 33 to cover the wiring layer 32 and the first dielectric film 22a exposed from the wiring layer 32. The wiring layer 23 and the protective film 25 are arranged on the upper part of the second dielectric film 22b. In the example shown in FIG. 10, the first electrode 21 and the second electrode 24 are at a low potential, and the third electrode 33 is at a high potential. Alternatively, the first electrode 21 and the second electrode 24 may be at a high potential, and the third electrode 33 may be at a low potential.

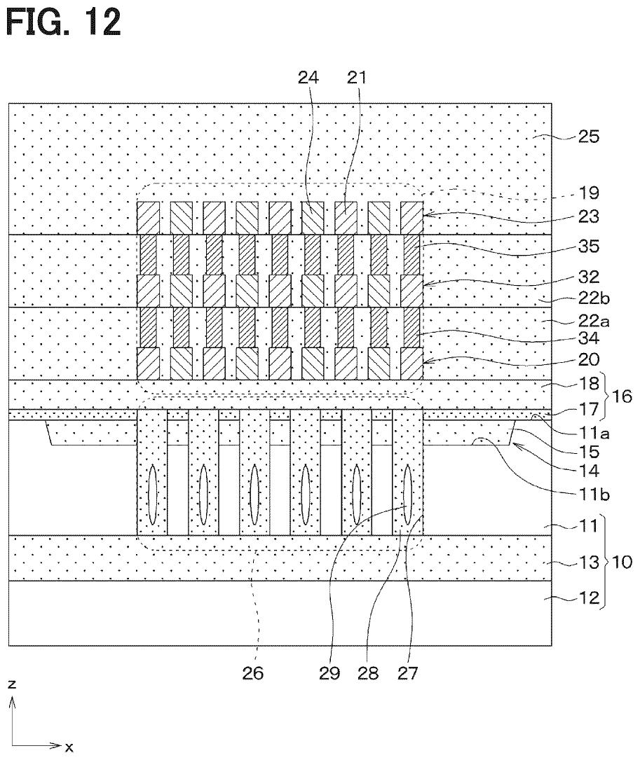

Furthermore, in the first and second embodiments, the upper surfaces of the first electrode 21 and the second electrode 24 are rectangular, but the first electrode 21 and the second electrode 24 may have other shapes. For example, as shown in FIGS. 11 and 12, the upper surfaces of the first electrode 21 and the second electrode 24 may be comb-shaped. In the example shown in FIGS. 11 and 12, two opposing comb-shaped electrodes are formed in the wiring layer 20. In the wiring layer 23, 32, electrodes having the same shape as the electrodes formed on the wiring layer 20 are formed on the upper part of the wiring layer 20. The electrodes formed in the wiring layer 20 and the electrodes formed in the wiring layer 32 are respectively connected by through holes 34 formed in the first dielectric film 22a. Furthermore, the electrodes formed in the wiring layer 32 and the electrodes formed in the wiring layer 23 are respectively connected by through holes 35 formed in the second dielectric film 22b. The through hole 34, 35 is formed by filling a conductive material such as tungsten in a through hole that penetrates the first dielectric film 22a and the second dielectric film 22b. In this manner, the first electrode 21 and the second electrode 24 each having a comb-like shape are formed in the wiring layer 20, 23, 32. The first electrode 21 and the second electrode 24 face each other in the x direction with the dielectric films 22a, 22b and the protective film 25 interposed therebetween, and a capacitance is formed at this facing portion. By forming the protective film 25 from a dielectric material such as SiO₂, the protective film 25 also functions as a dielectric film. In the example shown in FIGS. 11 and 12, the trench 27 reduces the effective opposing area between the first electrode 21 and the second electrode 24 and the first semiconductor substrate 11, thereby reducing the parasitic capacitance.

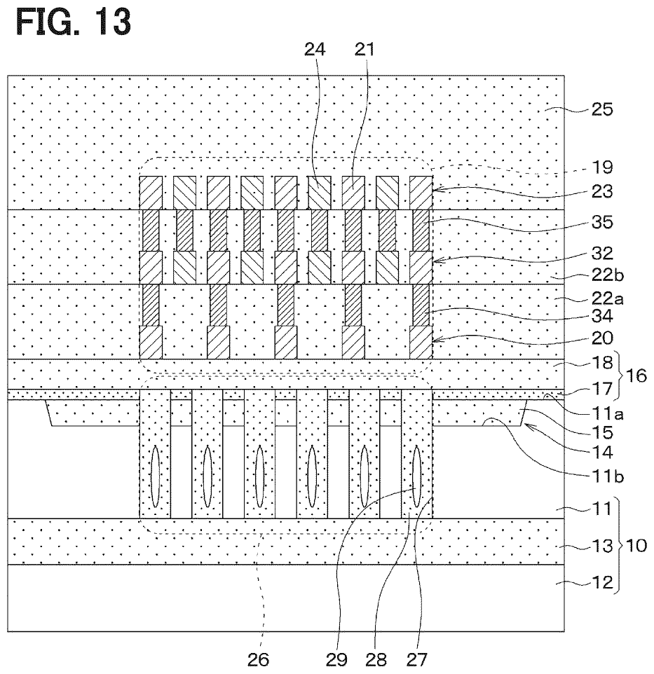

Furthermore, the number of wiring layers constituting the first electrode 21 and the second electrode 24 may be different. For example, in the examples shown in FIGS. 11 and 12, as shown in FIG. 13, the first electrode 21 may be formed in the wiring layers 20, 23, and 32, and the second electrode 24 may be formed in the wiring layers 23 and 32.

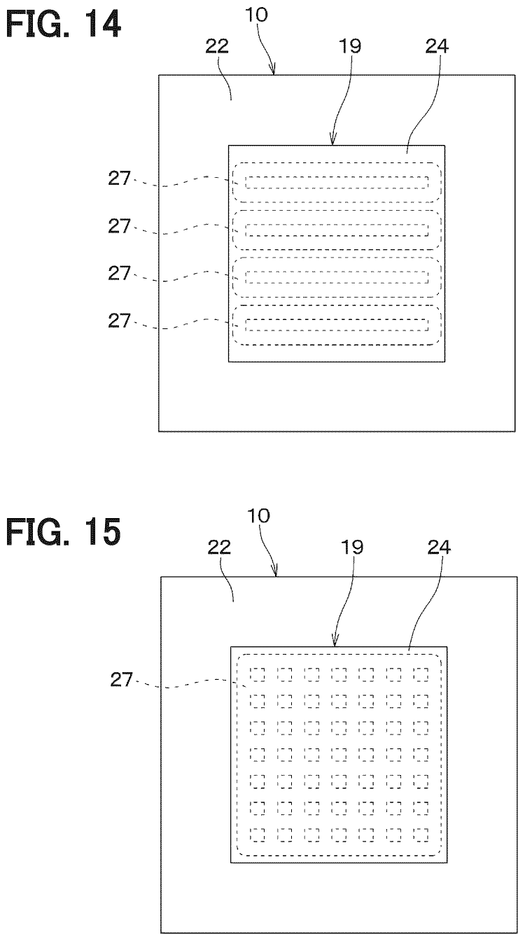

In the first embodiment, the multiple trenches 27 are formed in a concentric rectangular shape, but the trenches 27 may be formed in another shape, or only one trench 27 may be formed. For example, the trenches 27 may be arranged in a concentric pattern. Alternatively, as shown in FIG. 14, plural rectangular trenches 27 may be arranged in a stripe pattern. As shown in FIG. 15, the trenches 27 may be formed in a lattice pattern. Moreover, the trenches 27 of different shapes may be combined. If the opening area of trench 27 is increased, the effective opposing area between the capacitor 19 and the first semiconductor substrate 11 becomes smaller, but the upper surface of the interlayer film 16 becomes significantly recessed above the trench 27, making it difficult to form the wiring layer 20. In this regard, by making the trenches 27 lattice-shaped, the interlayer film 16 is supported by a portion of the first semiconductor substrate 11 surrounded by the trenches 27, and the effective opposing area between the capacitor 19 and the first semiconductor substrate 11 can be made smaller while reducing the unevenness of the upper surface of the interlayer film 16.

In the second embodiment, plural trenches 31 are formed and plural spaces 30 are formed by Si migration, but only one trench 31 and one space 30 may be formed.

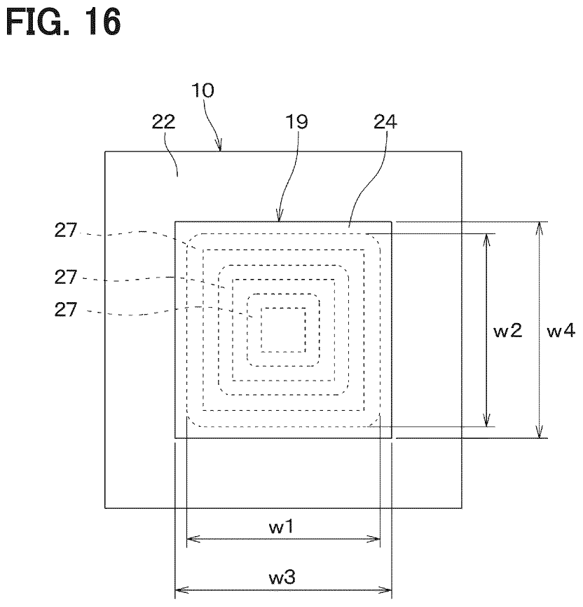

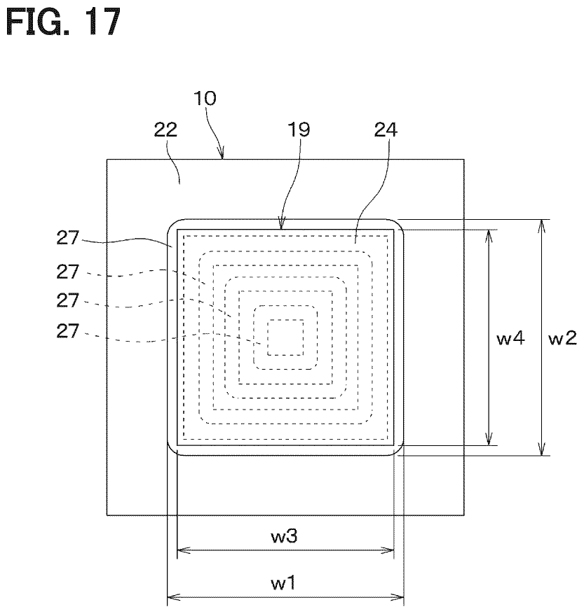

Furthermore, the width w1 and the width w3 may be different from each other, and the width w2 and the width w4 may be different from each other. For example, as shown in FIG. 16, the width w1, w2 may be smaller than the width w3, w4, and the trench 27 may be formed only inside the opposing region 26. Alternatively, as shown in FIG. 17, the width w1, w2 may be greater than the width w3, w4, and a part of the trench 27 may be formed outside the opposing region 26.

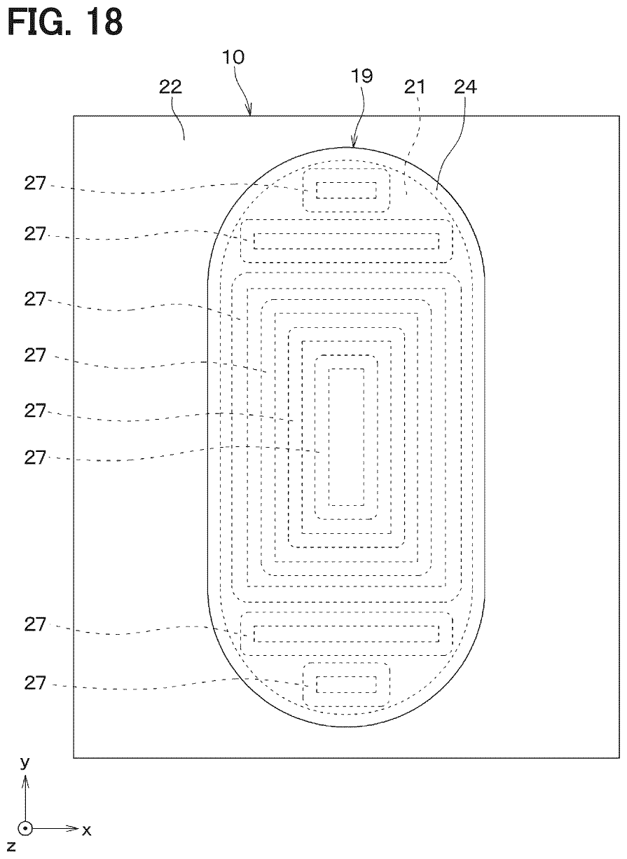

When the first electrode 21 and the second electrode 24 are stacked in the z direction with the dielectric film 22 interposed therebetween, the first electrode 21 and the second electrode 24 may have different dimensions. For example, as shown in FIG. 18, the first electrode 21 and the second electrode 24 may be formed in an elliptical shape with the y direction as the longitudinal direction, and the width of the second electrode 24 may be made larger than that of the first electrode 21 in both the x and y directions. In the example shown in FIG. 18, four trenches 27 opening in concentric rectangular shapes are formed in a region inside the outer edge of the first electrode 21. Further, two rectangular trenches 27 are arranged in the y direction, at on one side and the other side of the four trenches 27 in the y direction. The four sides of each trench 27 extend along the x direction or the y direction. The trench 27 formed on the outermost side in the y direction has a smaller width in the x direction than the adjacent trench 27. Even if the first electrode 21 and the second electrode 24 are elliptical in shape, by arranging the trenches 27 in this manner, the effective opposing area between the first electrode 21 and the first semiconductor substrate 11 can be significantly reduced.

Moreover, the buried film 28 may be made of one layer of SiO₂, and the opening of the trench 27 may be blocked by filling the buried film 28 once. In this case, the interlayer film 16 is configured to include a part of the buried film 28. By forming an oxide film having a thickness equal to or greater than half the width w5, the opening of the trench 27 can be blocked in a single filling process. By closing the opening of the trench 27 in one filling process, the space 29 becomes larger and the relative dielectric constant of the entire trench 27 becomes smaller, so that the parasitic capacitance can be further reduced.

Moreover, the first electrode 21 and the second electrode 24 may be formed in a single wiring layer. For example, the first electrode 21 and second electrode 24 shaped in comb-tooth may be formed as part of the wiring layer 20, and the capacitor 19 may be formed by the first electrode 21, the second electrode 24, and the dielectric film 22 stacked on top of the oxide film 18 exposed from the wiring layer 20.

What is claimed is:

1. A semiconductor device comprising:
a substrate; and
a capacitor provided on a surface of the substrate, wherein
the capacitor has two electrodes and a dielectric film interposed between the two electrodes, and
the substrate has a trench penetrating the substrate within an opposing region of the substrate opposing the capacitor.

2. The semiconductor device according to claim 1, further comprising:
a stacked board in which a first semiconductor substrate and a second semiconductor substrate are stacked with an insulating layer interposed therebetween, wherein the substrate is made of the first semiconductor substrate, and
the trench penetrates the first semiconductor substrate to reach the insulating layer.

3. The semiconductor device according to claim 1, further comprising:
an interlayer film disposed between the trench and the two electrodes, wherein
the interlayer film covers an opening of the trench, and
a space is formed inside the trench.

4. The semiconductor device according to claim 1, wherein
the trench is one of a plurality of trenches which are open in the surface of the substrate in a shape of concentric rectangles.

5. The semiconductor device according to claim 1, wherein
the trench is one of a plurality of trenches which are open in the surface of the substrate in a stripe pattern.

6. The semiconductor device according to claim 1, wherein the trench is open in the surface of the substrate in a lattice pattern.

7. The semiconductor device according to claim 1, wherein a trench region of the substrate in which the trench is formed is coincident with the opposing region at position and width in a direction parallel to the surface of the substrate.

8. The semiconductor device according to claim 1, wherein a trench region of the substrate in which the trench is formed is different from the opposing region at width in a direction parallel to the surface of the substrate.

9. The semiconductor device according to claim 8, wherein
a width of the opposing region in a direction parallel to the surface of the substrate is larger than that of the trench region.

10. A semiconductor device comprising:
a substrate; and
a capacitor disposed on a surface of the substrate, wherein
the capacitor has two electrodes and a dielectric film interposed between the two electrodes,
an opposing region of the substrate opposing the capacitor has a recess recessed from the surface of the substrate such that a thickness of the opposing region is smaller than that of an outer region of the substrate located on an outer side of the opposing region, and
a space is formed inside the opposing region.

11. The semiconductor device according to claim 10, wherein
the two electrodes are stacked in a direction perpendicular to the surface of the substrate, and
the dielectric film is interposed between the two electrodes.

12. The semiconductor device according to claim 10, wherein
each of the two electrodes is shaped in comb teeth, and
the two electrodes oppose to each other through the dielectric film in a direction parallel to the surface of the substrate.

13. A method of manufacturing a semiconductor device including a capacitor, comprising:
preparing a substrate;
forming the capacitor on a surface of the substrate, the capacitor being composed of two electrodes and a dielectric film disposed between the two electrodes; and
forming a trench penetrating the substrate in an opposing region of the substrate opposing the capacitor.

14. The method according to claim 13, wherein
the preparing of the substrate includes preparing a stacked board in which a first semiconductor substrate and a second semiconductor substrate are stacked with an insulating layer interposed therebetween, the first semiconductor substrate being the substrate, and
the forming of the trench includes forming the trench to penetrate the first semiconductor substrate and reach the insulating layer.

15. The method according to claim 13, further comprising:
forming an interlayer film between the trench and the two electrodes to close an opening of the trench; and
forming a space inside the trench.

16. The method according to claim 15, wherein
the interlayer film includes a buried film covering an inner wall of the trench, and
the forming of the space includes:
forming the buried film to cover the inner wall of the trench; and
closing the opening of the trench by an overhang of the buried film.

17. The method according to claim 15, wherein
an inner wall of the trench is covered with a first filling film and a second filling film arranged on the first filling film,
the interlayer film includes the second filling film, and
the forming of the space includes:
forming the first filling film to cover the inner wall of the trench;
forming the second filling film to cover the first filling film; and
closing the opening of the trench by an overhang of the second filling film.

18. The method according to claim 13, further comprising:
forming a space inside the substrate by softening the substrate by heat treatment and closing an opening of the trench by migration.
